(19) United States
(12) Patent Application Publication
(10) Pub. No.: US 2003/0024693 A1
(43) Pub. Date: Feb. 6, 2003

(54) Counter flow two pass active heat sink with heat spreader

(76) Inventors: Eric Hayes Petty, Fort Collins, CO (US); Andrew Douglas Delano, Fort Collins, CO (US)

Correspondence Address: AGILENT TECHNOLOGIES, INC., Legal Department, DL429, Intellectual Property Aministration, P.O. Box 7599, Loveland, CO, 80537-0599, US

(21) Appl. No.: 09/919,526

(22) Filed: Jul. 31, 2001

(51) Int. Cl. F28F 1/00; F24H 3/02; F28F 7/00; H05K 7/20; H01L 23/34

(52) U.S. Cl. 165/121; 165/185; 361/697; 257/722

(57) ABSTRACT

The heat removal ability of a finned counter flow two pass active heat sink is increased by placing a heat spreader at the location where the heat flux enters the active heat sink a heat. This allows a more uniform distribution of the entering heat flux into the cross section of the active heat sink, increasing its ability to transfer that heat to the air flow. Copper is a good choice for the heat spreader. It can be intimately bonded to the material of choice for the body of the active heat sink (aluminum). Intimate bonding assures good heat transfer from the spreader into the base of the balance of the heat sink. The heat spreader can be hot rolled onto aluminum billets, the result cut into workpieces and then shaped. Discs of copper can be friction welded to biscuits of aluminum rod with spinning, and then shaped. Or, a disc of copper can be forge welded onto a biscuit of aluminum, which operation may include a partial forging of the aluminum into a near final shape.

### REFERENCE TO RELATED APPLICATION

The subject matter of this Application is related to that disclosed in U.S. Pat. No. 5,785,116 entitled FAN ASSISTED HEAT SINK, filed by Wagner on Feb. 1, 1996 and issued on Jul. 28, 1998. That Patent describes a particular type of internal fan heat sink for microprocessors, large power VLSI devices and the like, that dissipate a sufficient amount of power to require a substantial heat sink. The instant invention pertains to a manner of making an improved version of that same type of internal fan heat sink, which heat sink has a number of unique properties that do not readily lend themselves to summary description: it is not a garden variety heat sink with a fan grafted onto it. For this reason U.S. Pat. No. 5,785,116 is hereby expressly incorporated herein by reference, so that all the unique properties of that active heat sink, including its manner of operation and final shaping during manufacture, will be fully available for the understanding of this Disclosure.

### BACKGROUND OF THE INVENTION

Integrated circuits are becoming more and more powerful all the time. Not only is this true in the sense that they do more, and do it faster (e.g., in the field of microprocessors and FPGA's—Field Programable Gate Arrays), but these newer parts dissipate amounts of power that were unimaginable just a few years ago. For example, there are parts under development that will dissipate one hundred and thirty watts and will need to get rid of the attendant heat through a surface area of about one square inch. There are exotic methods of heat removal that are possible, including heat pipes, chilled water cooling and even actual refrigeration. In the main, these techniques are cumbersome or expensive, and are not suitable for high volume commercial applications in modestly priced retail equipment, such as personal computers and workstations.

The active (meaning fan assisted) heat sink described in the above incorporated Patent to Wagner was developed to deal with this situation. It is a heat sink having a spiral of fins that surround a fan around its circumferential periphery and are in its discharge path. (In other designs the fins are not a spiral, but are straight up and down. We might say they form a ring of straight fins. They occupy the same general region as do the spiral fins, however.) This makes Wagner's active heat sink a two pass device, since the design draws a portion of its air in through the periphery (one pass) and then discharges it through more fins (second pass). It is a counter flow device, since the path of heat flow is generally opposite to the direction of air flow, so that as air is heated through contact with the fins it encounters still warmer fins as it continues along its path. This ensures greater heat transfer by maintaining temperature differential between the cooling air and the fins that are to give up their heat to the air. In addition, Wagner's active heat sink has a number of other desirable properties, such as low noise and an absence of extra mating surfaces that interfere with heat flow.

The preceding several sentences are a brief description of Wagner's active heat sink, but it is probable that, unless the reader has actually seen one, he or she will not have a completely satisfactory mental image of just what such a fine active heat sink really looks like. We can cure that by including certain of the figures from the Wagner Patent, which we have done. However, that still leaves us with the problem of a nice tidy way to refer to it: “finned counterflow two pass active heat sink” is accurate as far as it goes, but is also pretty cumbersome. Various heat sinks of this design are on the market, offered by Agilent Technologies, Inc. under the trade name “ArctiCooler”, but it would be a risky business to rely on that, since we can't be sure what that term will eventually come to encompass. So, we will do as we have already begun to do above: we shall call the kind of fan-assisted heat sink described above and in the Specification of the Wagner Patent a “Wagner active heat sink”, or depending upon the grammatical needs at the time, “Wagner's active heat sink”. By availing ourselves of this coined phrase, we shall avoid much inconvenience. On the principle that whatever makes for shorter sentences is good, when it is entirely clear that we are indeed referring to a Wagner active heat sink, we shall feel free to call it an “active heat sink,” or perhaps just a “heat sink,” as a further simplification.

It will, of course, be appreciated that as the Wagner active heat sink gains further acceptance and additional needs and applications develop, the exact size, relative shape and so forth will evolve over time. Thus, there are already small ones, medium and large sizes, and extra heavy duty ones, etc. Accordingly, it will be understood that the specific examples shown in U.S. Pat. No. 5,785,116 (Wagner) are merely illustrative of a larger general class of active heat sinks (Wagner active heat sinks), and that such specific details as the number of fins, whether they are straight or spiral, their thickness compared to their height, the number of blades on the fan, whether the thing is tall or squat, etc., are not details included in our meaning, or determined by use, of the term “Wagner active heat sink”.

To continue, then, as good as the Wagner active heat sink is, it is still the case that anything that can be done to enhance efficiency is desirable, since the wattages to be dissipated are increasing to such a large degree. One way to get an active heat sink that handles more heat is to make it bigger, but it would be better if there were a way to get an existing size to handle more heat without making it bigger (and also heavier). What to do?

### SUMMARY OF THE INVENTION

A solution to the problem of increasing the heat removal ability of a Wagner active heat sink is to place at the location where the heat flux enters the active heat sink a heat spreading layer of material (a heat spreader) having lower thermal resistance than the material from which the remaining portion of the active heat sink is fabricated. This allows a more uniform distribution of the entering heat flux into the cross section of the active heat sink, increasing its ability to transfer that heat to the air flow. Copper is a good choice for the heat spreader, since it has very low thermal resistance, is relatively inexpensive, and can be intimately bonded to the material of choice for the body of the active heat sink (aluminum). Intimate bonding is important to assure good heat transfer from the spreader into the base of the balance of the heat sink. The heat spreader can be hot rolled onto aluminum billets, the result cut into workpieces and shaped as disclosed in Wagner. Discs of copper can be friction welded to biscuits of aluminum rod with spinning, and then shaped as in Wagner. Or, a disc of copper can be forge welded onto a biscuit of aluminum, which operation may include a partial forging of the aluminum into a near final shape.

### BRIEF DESCRIPTION OF THE DRAWINGS

FIG. 1 is a top perspective view of a (prior art) Wagner active heat sink;

FIG. 2 depicts a hot rolling step for a process of fabricating a Wagner active heat sink having a heat spreader;

FIGS. 3A and 3B depict separating steps for a fabrication process pertaining to FIG. 2;

FIG. 4 depicts a forging step for a process of fabricating a Wagner active heat sink having a heat spreader;

FIG. 5 depicts a machining step for a process of fabricating a Wagner active heat sink

FIG. 6 depicts a friction welding step for a process of fabricating a Wagner active heat sink; and

FIG. 7 depicts a hot forging step for a process of fabricating a Wagner active heat sink.

### DESCRIPTION OF A PREFERRED EMBODIMENT

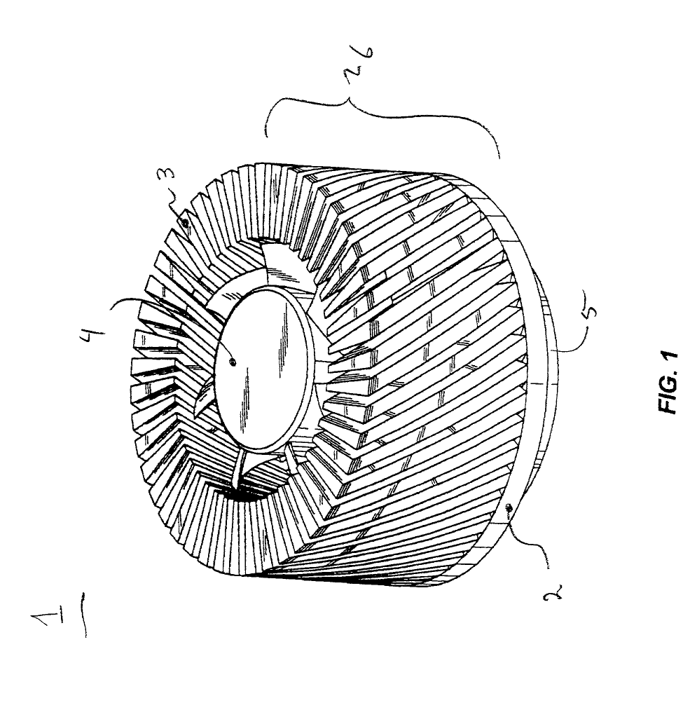

Refer now to FIG. 1, wherein is shown a top perspective view 1 of a Wagner active heat sink 6. There is an annular ring 3 of spiral cooling fins, preferable of aluminum, within the center of which is mounted a fan 4. Not shown is the IC (Integrated Circuit) or other device that is to be cooled. It would be in contact with the underside of a heat entry pedestal 5, located directly beneath the hub of the fan. The heat entry pedestal 5 is actually a lower portion of a layer of copper 2 that forms a heat spreader along the bottom of the active heat sink assembly 6.

The heat spreader is a compromise—we would really like to have the performance of a heat sink fabricated of all copper. There is no technical reason that cannot be done, nor is copper prohibitively expensive (as are certain exotic materials). No, it is more a matter of weight. Copper is considerably heavier than aluminum, and weight is important. We don't want to create a heavy heat sink that is the five hundred pound gorilla inside a light duty plastic enclosure of a merchant product . . . . So, even though most copper has about half the thermal resistance of aluminum, we are not (yet, anyway) so desperate for heat handling performance that we are forced to accept the added weight of all copper construction. It turns out that we can get a ten or fifteen percent increase in heat handling ability if the copper heat spreader is thick enough, and still have the majority active heat sink be of aluminum, and with only a slight increase in weight that is way less than the weight for an all copper design for the same heat handling ability.

Those familiar with copper will appreciate that there are various types and alloys of copper found in commerce. Some have higher thermal conductivity than others, and if all other things are equal, the best choice is the type with the higher thermal conductivity.

In FIG. 1 the spaces between the fins are shown as extending downward toward the top of the heat spreader until they actually reach it. This is one of three possibilities (cases) concerning the location of the boundary between the copper and the aluminum. The first is that the boundary is lower than the bottoms of the spaces between the fins. The second is as shown, where the boundary is at the bottom of the spaces. The third is that the bottom of the spaces extends down into the copper heat spreader 2. Which of the three is selected for use will depend primarily upon factors related to needed thermal conductivity, and perhaps upon considerations related to machining. The issue of relying on the strength of the bond, which is essentially a weld between dissimilar metals, in the second and third cases is not really an issue at all, since the weld is quite strong provided it is not defective (a process control issue). The aluminum portion of fins separating from the underlying copper in parts fabricated as in case three have not been a problem.

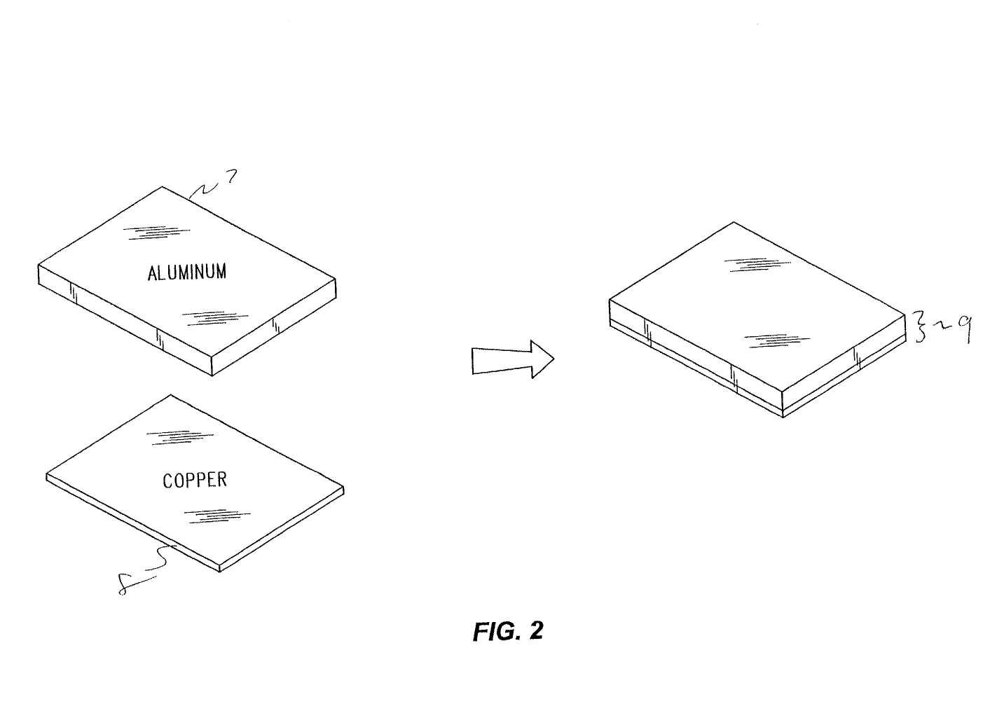

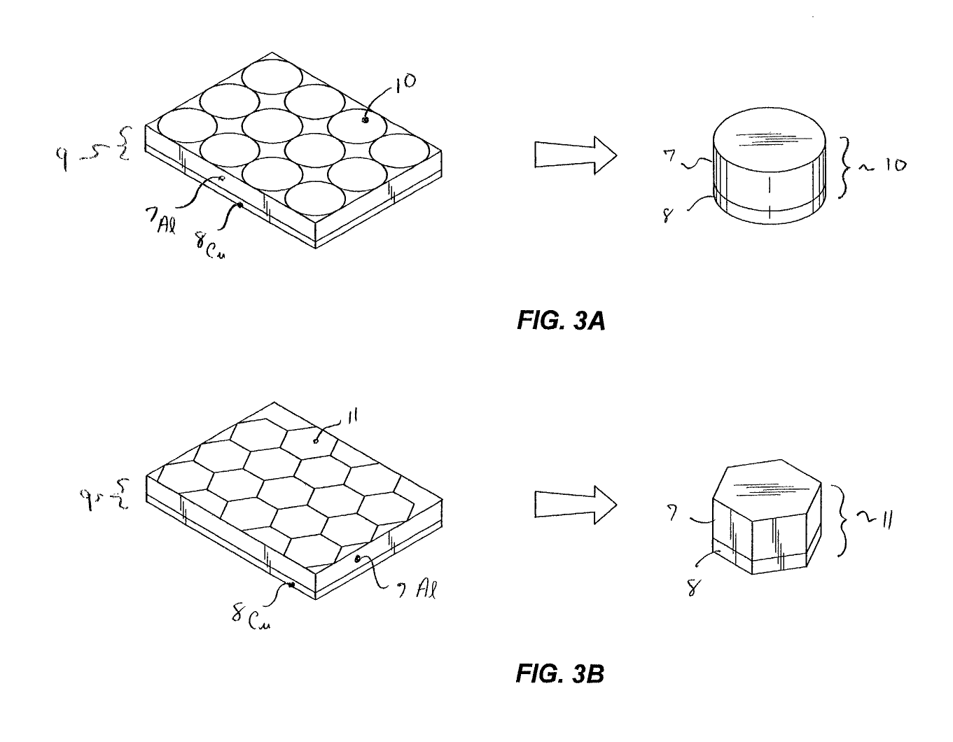

Given that we have a properly shaped chunk of aluminum with a copper slab intimately bonded to it, we can proceed according to the teachings of the incorporated Wagner Patent for machining a finished part. In this connection, refer now to FIGS. 2, 3A and 3B. FIG. 2 shows that a slab or billet of aluminum 7 and a sheet or slab of copper 8 may be bonded together for intimate thermal contact to form a layered workpiece 9. The aluminum can range in thickness up to, say, about two inches, and the copper can be can be in the range of from one eighth to one half inch in thickness. The process used to perform the bonding may be a conventional one called hot rolling. The aluminum and copper are cleaned and heated (typically to two thirds their melting point), and then rolled together in a rolling mill. There are in commerce vendors that perform these operations, such as Clad Metal Product of Boulder, Colo., 80301, and located 5635 So. Pine Rd.

Now refer to FIGS. 3A and 3B, which are depictions of a separation step for a slab 9 of copper clad aluminum. In the case of FIG. 2A, if the slab 9 is not too thick then circular biscuits 10 can be punched out. If that is not practical, they may be extracted as cores using a hole saw, or cut apart using a suitable routing apparatus. FIG. 3A illustrates a similar separation step to obtain a non-round biscuit 11 whose shape formed a mosaic upon the slab 9. The idea is the reduction of scrap. And although we have not shown it, a useful shape for the mosaic on the slab 9 of FIG. 3B is a square, or perhaps a rectangle. Those shapes are readily separated by sawing. And if a square creates too much waste when the biscuit 11 is later turned on a lathe to make it round, then let it stay square! Who says we can't make a square Wagner heat sink?

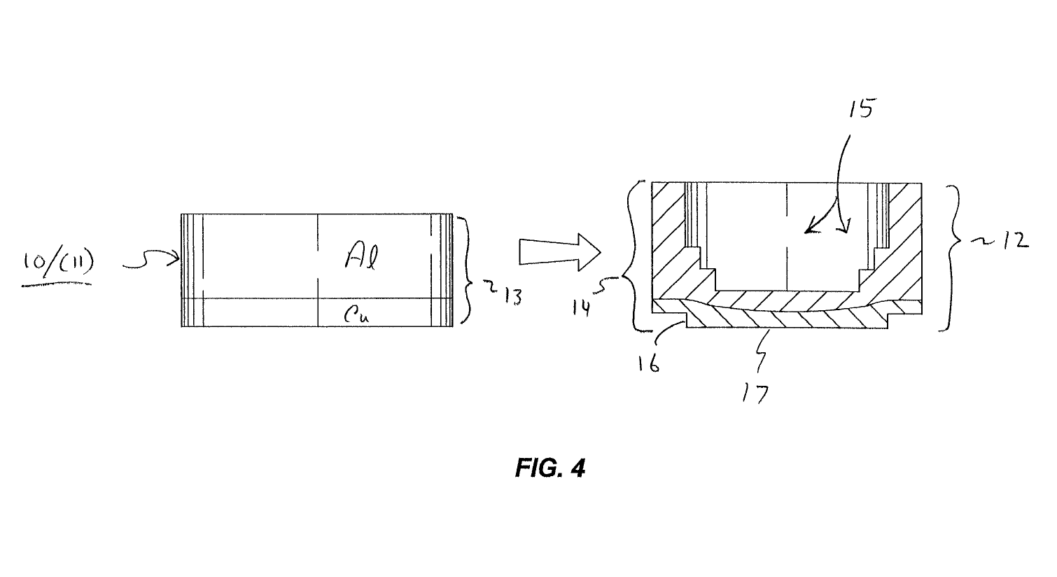

Having supplied ourselves with copper clad aluminum biscuits of suitable thicknesses and shape, we begin the process of forming the actual final shape. Referring now to FIG. 4, note that the copper clad biscuit 10 (or 11) is (cold) forged to near its net shape. This is, again, a conventional process that vendors in commerce are equipped to handle. For example, a biscuit that is, say, about an inch thick, can be forged using suitable dies in a four hundred ton press. The result is the stamping 12, shown in the right hand portion of FIG. 4.

Stamping 12 has some properties of interest. To begin with, it has a height 14 that is greater than that 13 of the original biscuit 10/(11). Most of this growth in height is in the aluminum, which flows during the forging. It flows out of the cavity 15, which is left with any shoulders needed to support other components or to provide a particular thermal resistance at that location within the heat sink body. There may also be some change the shape of the layer of copper that is to be the heat spreader. If desired, an annular shoulder 16 can be produced around a heat entry pedestal 17 (described as 5 in FIG. 1). Present Wagner heat sinks find this pedestal useful for weight reduction and in producing mounting clearance, etc. At some time in the future, however, it may be desirable to dispense with the pedestal, and have simply a flat bottom that is also a heat spreader layer of copper of sufficient thickness. (There are some heat flux dynamics involved here, concerning the size of the aperture through which the flux enters the heat sink. The path for the flux can get thin around the periphery if it is thick enough in the center. One way of achieving this is with an exterior pedestal. This is well understood optimization. What we are suggesting is that in some applications such optimizations may be viewed as unneeded, and a brute force approach of “make it thick all over” preferred instead. One the other hand, such a heat entry pedestal allows a relative weight reduction, which can be important.)

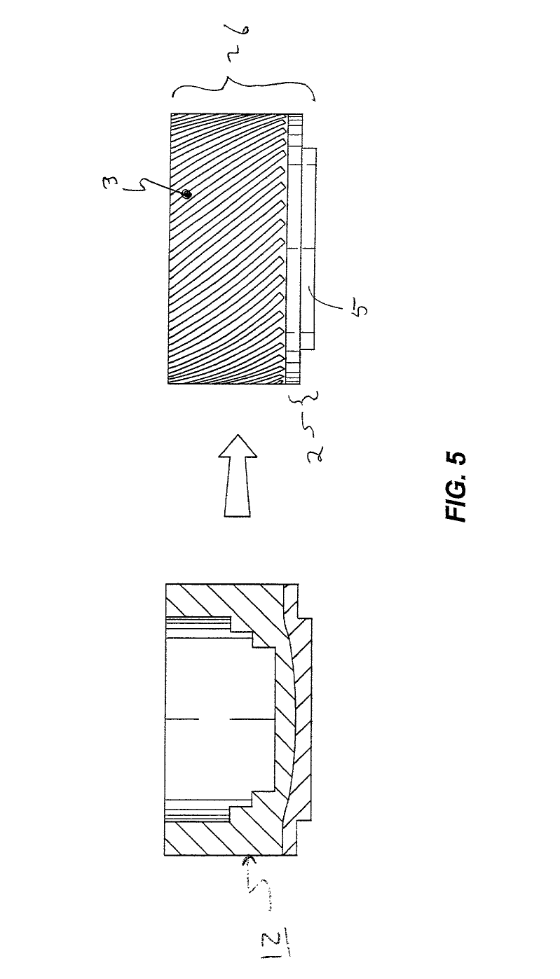

With reference now to FIG. 5, therein is depicted the subsequent machining steps that turn the stamping 12 into a finished part 6 that is a Wagner active heat sink with a finned counter flow two pass active heat sink 3 having a copper heat spreader 2 on the bottom. (The motorized fan is not shown.) See the incorporated Patent to Wagner for description of how to proceed with such machining.

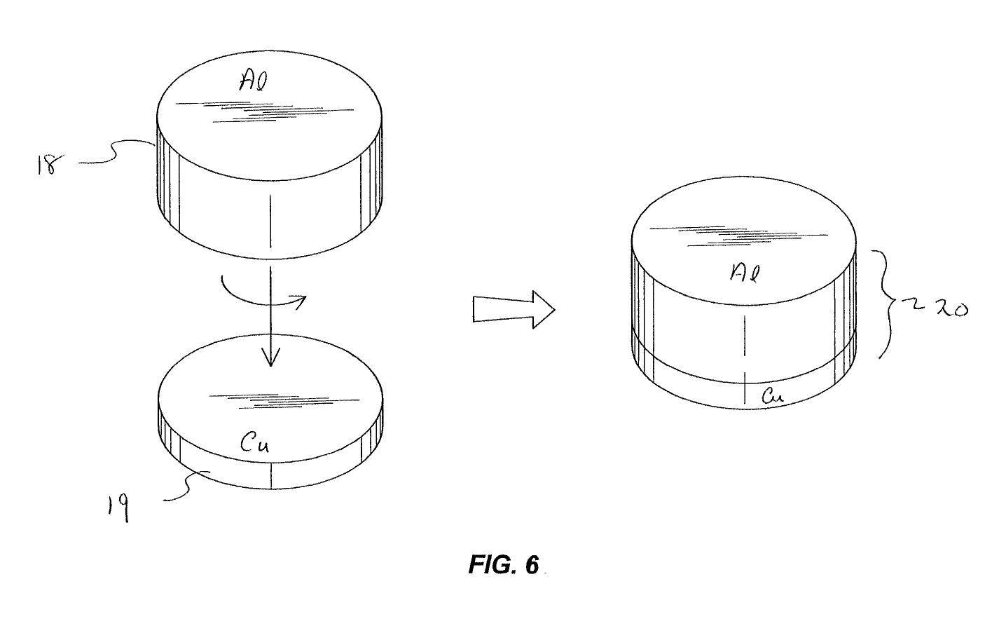

We now consider alternate methods for creating biscuits 10 of copper clad aluminum. Refer now to FIG. 6, wherein is depicted a friction welding process (spinning) that may be used to intimately bond a copper disc 19 to a disc 18 of aluminum. Large thickness are less of an issue here than they might be in connection with the hot rolling and separation steps of FIGS. 2 and 3. In fact, in FIG. 6 the discs must be sufficiently thick and of adequate diameter (say, two to four inches) that they can be securely gripped. Read on.

In this conventional method of welding, one of the discs is rotated relative to the other, about a common central axis, at say, 470 RPM. The rotation involves a accelerating a heavy flywheel that produces, say, 3,000 Ft²Lbs. At this point the discs are not yet touching. After all that energy is stored in the flywheel/disc combination, a clutch disconnects them from the prime mover and the two discs are brought together with a force of, say, 150,000 Lbs. In less than a second the rotation ceases, the weld has been made, and a copper clad aluminum biscuit 20 has been produced. (The process parameters given are for three inch diameter stock.) It is truly an awesome thing to watch. Those who are familiar with this process of spin welding claim that is a solid state process that does not involve the phase change to melted (liquid) material.

This method has some advantages, among them being that discs of copper and aluminum can be easily obtained by cutting them from the ends of readily available round stock.

Once the copper clad aluminum biscuit 20 has been produced, it can be used in place of place of biscuit 13 of FIG. 4, and the rest of the fabrication process will be as already described.

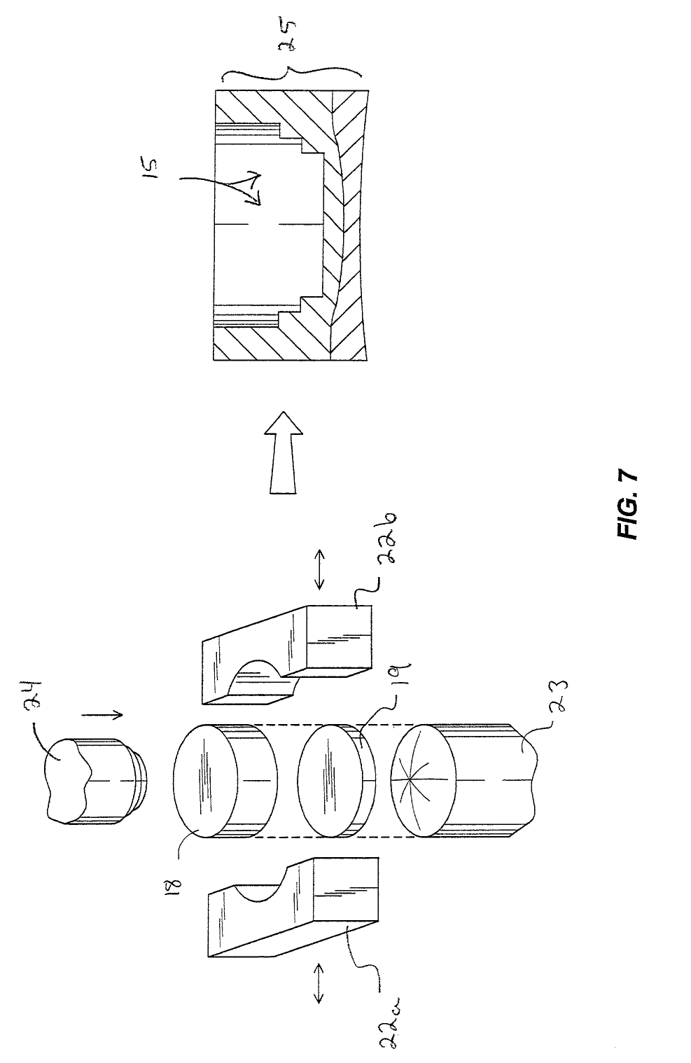

There is yet another alternate process for producing a copper clad aluminum biscuit that can be used in place of the hot rolled and separated one 13 of FIGS. 3A and 4. Refer now to FIG. 7, wherein is depicted a hot forging process that starts with a disc 18 of aluminum and a disc 19 of copper, which as in the case of FIG. 6, may be obtained by cuts on round stock. The discs 18 and 19 are cleaned and prepared to have smooth surfaces. They are then heated and placed between die pieces 22a and 22b. The copper disc rest on an anvil post 23 having a slightly spherical top. Next, a ram 24 is forced down into the aluminum.

Two things happen. First, the two discs come into contact. Because of the spherical top of the anvil post 19, the force exerted by the ram 24 will be experienced principally in the center of the discs. At this point the center is welded, as if by hot rolling, but at a point or small region, rather than along a thick line. The copper and aluminum will yield and deform, allowing a surrounding region (an expanding circle) to next experience the force of the ram, and so on. It is might be termed “radial hot rolling.” The second thing that happens is that the desired cavity 15 is formed in the aluminum, with an attendant growth in height of the aluminum portion of the forge welded biscuit 25. After the biscuit 25 is removed and allowed to cool, its curved bottom can be turned flat, and it is ready to replace stamping 12 in FIG. 5, whereupon the remaining fabrication steps are as previously set out.

We claim:

1. A finned two pass counter flow active heat sink fabricated from copper clad aluminum to provide a copper heat spreader as the heat entry portion.

2. A finned two pass counter flow active heat sink as in claim 1 wherein the aluminum is clad with copper in a hot rolling operation.

3. A finned two pass counter flow active heat sink as in claim 1 wherein the aluminum is clad with copper with a friction welding operation.

4. A finned two pass counter flow active heat sink as in claim 1 wherein the aluminum is clad on one side with copper in a hot forging operation that also forges the aluminum to produce on an opposite side an internal cavity that provides a location to mount a motorized fan.
